(19) United States
(12) Patent Application Publication
(10) Pub. No.: US 2026/0280582 A1
(43) Pub. Date: Sep. 17, 2026

(54) CODE TABLE GENERATION DEVICE, MEMORY SYSTEM, AND CODE TABLE GENERATION METHOD

(71) Applicant: Kioxia Corporation, Tokyo (JP)

(72) Inventors: Youhei FUKAZAWA, Yokohama (JP); Masato SUMIYOSHI, Yokohama (JP); Sho KODAMA, Kamakura (JP); Keiri NAKANISHI, Kawasaki (JP)

(73) Assignee: Kioxia Corporation, Tokyo (JP)

(21) Appl. No.: 19/321,647

(22) Filed: Sep. 8, 2025

(30) Foreign Application Priority Data
Mar. 17, 2025 (JP) 2025-042417

(51) Int. Cl. H03M 7/42

(52) U.S. Cl. CPC H03M 7/42

(57) ABSTRACT

According to one embodiment, a code table generation device includes circuitry. The circuitry is configured to add all the appearance frequencies of the symbols input in a certain period and calculate a sum of the appearance frequencies of all the symbols input in the certain period. The circuitry is configured to calculate a sum of appearance frequencies of the symbols ranked M−1 or higher in a frequency table sorted in descending order. The circuitry is configured to subtract the calculated sum of the appearance frequencies of symbols ranked M−1 or higher from the calculated sum of the appearance frequencies of all the symbols and calculate a sum of the appearance frequencies of symbols ranked M or lower in the frequency table.

### CROSS-REFERENCE TO RELATED APPLICATIONS

This application is based upon and claims the benefit of priority from Japanese Patent Application No. 2025-042417, filed Mar. 17, 2025, the entire contents of which are incorporated herein by reference.

### FIELD

Embodiments described herein relate generally to a code table generation device, a memory system, and a code table generation method.

### BACKGROUND

Dynamic Huffman coding is a variable length coding method that dynamically generates a code table based on an appearance frequency of a symbol to be coded. The code table indicates a correspondence between a symbol and a codeword allocated to the symbol. In the dynamic Huffman coding, a short codeword is allocated to a symbol having a high appearance frequency, and a long codeword is allocated to a symbol having a low appearance frequency.

More specifically, in the dynamic Huffman coding, for example, a Huffman tree having each of one or more types of symbols that have appeared as a leaf node is constructed. Then, a codeword is assigned to each symbol by using the constructed Huffman tree.

Processing of constructing a Huffman tree and assigning a codeword to each symbol requires a processing amount proportional to the type of the symbol that has appeared. Therefore, in a case where there are many types of symbols that have appeared, it takes a lot of time to process the code table generation, or the circuit scale (for example, the number of gates) of the device has to be increased to complete the code table generation within a specific time.

### BRIEF DESCRIPTION OF THE DRAWINGS

FIG. 1 is a block diagram illustrating an example of a configuration of an information processing system including a code table generation device according to an embodiment.

FIG. 2 is a block diagram illustrating an example of a configuration of a code table generation device according to a first comparative example.

FIG. 3 is a flowchart illustrating an example of a procedure of code table generation processing executed in the code table generation device according to the first comparative example.

FIG. 4 is a diagram illustrating a configuration example of a frequency table used in the code table generation device according to the first comparative example.

FIG. 5 is a diagram for specifically describing the code table generation processing executed in the code table generation device according to the first comparative example.

FIG. 6 is a diagram for specifically describing the code table generation processing executed in the code table generation device according to the first comparative example.

FIG. 7 is a block diagram illustrating an example of a configuration of a code table generation device according to a second comparative example.

FIG. 8 is a diagram illustrating a configuration example of a frequency table used in the code table generation device according to the second comparative example.

FIG. 9 is a diagram for specifically describing processing of inserting and sorting an entry corresponding to a representative symbol executed in the code table generation device according to the second comparative example.

FIG. 10 is a diagram illustrating an example of a pseudo program for allocating a code bit string to a symbol, the pseudo program being executed in the code table generation device according to the second comparative example.

FIG. 11 is a block diagram illustrating an example of a configuration of a compression device including the code table generation device according to the embodiment.

FIG. 12 is a block diagram illustrating an example of a circuit configuration of a total frequency addition unit included in the code table generation device according to the embodiment.

FIG. 13 is a flowchart illustrating an example of a procedure of encoding processing executed in the compression device including the code table generation device according to the embodiment.

FIG. 14 is a flowchart illustrating an example of a procedure of the code table generation processing executed in the code table generation device according to the embodiment.

### DETAILED DESCRIPTION

In general, according to one embodiment, a code table generation device includes circuitry. The circuitry is configured to generate a frequency table including a plurality of symbols and a plurality of appearance frequencies respectively associated with the plurality of symbols based on an appearance frequency of each symbol of the symbols input in a certain period. The circuitry is configured to add all the appearance frequencies of the symbols input in the certain period and calculate a sum of the appearance frequencies of all the symbols input in the certain period. The circuitry is configured to rearrange the plurality of symbols in descending order of appearance frequency in the frequency table. The circuitry is configured to acquire a partial table including symbols ranked M−1 or higher from a frequency table including the plurality of rearranged symbols (M is an integer of 3 or higher), and calculate a sum of appearance frequencies of the symbols ranked M−1 or higher. The circuitry is configured to subtract the calculated sum of the appearance frequencies of symbols ranked M−1 or higher from the calculated sum of the appearance frequencies of all the symbols and calculate a sum of the appearance frequencies of symbols ranked M or lower in the frequency table including the plurality of rearranged symbols. The circuitry is configured to add one symbol corresponding to the sum of the appearance frequencies of the symbols ranked M or lower to the partial table, and rearrange the symbols ranked M−1 or higher and the one symbol in descending order of appearance frequency in a partial table after addition. The circuitry is configured to generate a first code table corresponding to M symbols including the rearranged symbols ranked M−1 or higher and the one symbol. The circuitry is configured to equally allocate a code length to the symbols ranked M or lower and generate a second code table corresponding to the symbols ranked M or lower using the allocated code length. The circuitry is configured to expand, at an end of a codeword corresponding to the one symbol included in the first code table, a codeword corresponding to the symbol ranked M or lower included in the second code table, and generate a code table corresponding to all the symbols.

Hereinafter, embodiments will be described with reference to the drawings.

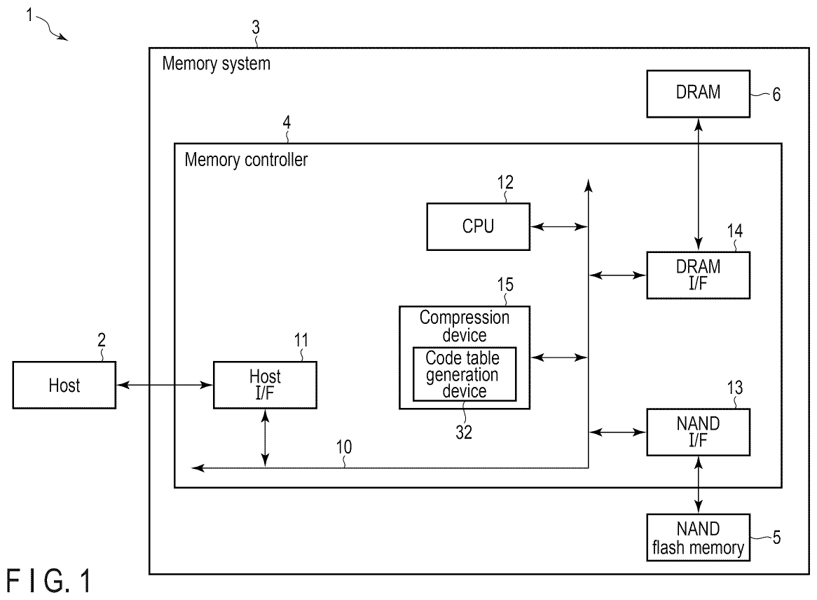

FIG. 1 illustrates an example of a configuration of an information processing system including a code table generation device according to an embodiment. An information processing system 1 includes a host device 2 (hereinafter, referred to as a host 2) and a memory system 3.

The memory system 3 is a semiconductor storage device configured to write data to a non-volatile memory such as a NAND flash memory 5 and read data from the nonvolatile memory. The memory system 3 is realized, for example, as a solid state drive (SSD) including the NAND flash memory 5. Hereinafter, a case where the memory system 3 is realized as the SSD will be exemplified, but the memory system 3 may be realized as a hard disk drive (HDD).

The host 2 may be a storage server that saves a large amount of various data items in the memory system 3, or may be a personal computer.

The memory system 3 can be used as a storage of the host 2. The memory system 3 may be built into the host 2 or may be connected to the host 2 via a cable or a network.

An interface for connecting the host 2 and the memory system 3 conforms to SCSI, Serial Attached SCSI (SAS), ATA (AT Attachment), Serial ATA (SATA), PCI Express (PCIe) (registered trademark), Ethernet (registered trademark), Fibre channel, NVM Express (NVMe) (registered trademark), and the like.

The memory system 3 includes a memory controller 4 and the NAND flash memory 5. The memory controller 4 can be realized by controller circuitry such as a system-on-a-chip (SoC).

The memory system 3 may include a random access memory (RAM) which is a volatile memory, for example, a dynamic random access memory (DRAM) 6. Alternatively, a RAM such as a static random access memory (SRAM) may be built into the memory controller 4. The DRAM 6 may be built into the memory controller 4.

The DRAM 6 is a volatile memory. The RAM such as the DRAM 6 is provided with, for example, a storage area of firmware (FW) and a cache area of a logical-to-physical address conversion table.

The NAND flash memory 5 includes a plurality of blocks. Each block includes a plurality of pages. One block functions as a minimum erase unit. The block may also be referred to as an “erasure block” or a “physical block”. Each page includes a plurality of memory cells connected to the same word line. One page is a unit of a data write operation and a data read operation. The word line may be used as a unit of the data write operation and the data read operation.

The allowable number of program/erase cycles for each block has an upper limit (maximum P/E cycle count). One P/E cycle of a certain block includes an erase operation for setting all memory cells in the block to an erase state, and a write operation for writing data to each page of the block.

The memory controller 4 includes, for example, a host interface (host I/F) 11, a CPU 12, a NAND interface (NAND I/F) 13, a DRAM interface (DRAM I/F) 14, and a compression device 15. The host I/F 11, the CPU 12, the NAND I/F 13, the DRAM I/F 14, and the compression device 15 can be interconnected via a bus 10.

The memory controller 4 is electrically connected to a NAND flash memory 5 via the NAND I/F 13 that supports interface standards such as Toggle DDR and Open NAND Flash Interface (ONFI). The NAND I/F 13 functions as NAND control circuitry configured to control the NAND flash memory 5.

The memory controller 4 is configured to control the NAND flash memory 5.

The memory controller 4 may function as a flash translation layer (FTL) configured to execute data management and block management of the NAND flash memory 5. The data management executed by the FTL includes (1) management of mapping information indicating a correspondence relationship between each logical address and each physical address of the NAND flash memory 5, and (2) processing for concealing a difference between the data read operation/data write operation in units of pages and the data erase operation in units of blocks. The block management includes defective block management, wear leveling, and garbage collection.

The logical address is an address used by the host 2 to address a storage region of the memory system 3. Management of mapping between each logical address and each physical address is executed using the logical-to-physical address conversion table. The memory controller 4 manages mapping between each logical address and each physical address in a specific management size unit using the logical-to-physical address conversion table. A physical address corresponding to a certain logical address indicates a physical storage location in the NAND flash memory 5 to which the data of the logical address is written. The logical-to-physical address conversion table may be loaded from the NAND flash memory 5 to the DRAM 6 when the memory system 3 is powered on.

Writing of data to one page is possible only once per one P/E cycle. Therefore, the memory controller 4 writes update data corresponding to a certain logical address not to a physical storage location where previous data corresponding to this logical address is stored but to another physical storage location. Then, the memory controller 4 invalidates the previous data by updating the logical-to-physical address conversion table to associate the logical address with another physical storage location.

The host I/F 11 is a hardware interface that communicates between the memory system 3 and the host 2 that is an external device of the memory system 3. The host I/F 11 includes circuitry that receives various commands, for example, input/output (I/O) commands and various control commands from the host 2. The I/O command may include a write command and a read command. The control command may include an unmap command (trim command) and a format command. The host I/F 11 includes circuitry that transmits a response or data corresponding to a command to the host 2.

The DRAM I/F 14 functions as DRAM control circuitry configured to control access to the DRAM 6.

The CPU 12 is a processor configured to control the host I/F 11, the NAND I/F 13, the DRAM I/F 14, and the compression device 15. The CPU 12 performs various processing procedures by executing the FW loaded in the DRAM 6. That is, FW is a control program for controlling the operation of the CPU 12. In addition to the FTL processing described above, the CPU 12 can execute command processing or the like for processing various commands from the host 2. Part or all of the FTL processing and the command processing may be executed by dedicated hardware in the memory controller 4.

The compression device 15 is a Huffman encoding unit that encodes data to be written to the NAND flash memory 5 to compress the data. For example, the CPU 12 inputs write data received in response to reception of a write command from the host 2 to the compression device 15 as plain text data. The compression device 15 encodes the plaintext data input from the CPU 12.

The compression device 15 has a configuration for realizing dynamic Huffman coding defined by, for example, deflate or gzip in order to compress data.

The dynamic Huffman coding is a variable length coding method that dynamically generates a code table (coding table) using an appearance frequency of a symbol to be coded. The code table includes information indicating N types of symbols and N variable length codes (codewords) respectively associated with the N types of symbols. Here, N is an integer of 4 or more. In the dynamic Huffman coding, a short codeword is allocated to a symbol having a high appearance frequency, and a long codeword is allocated to a symbol having a low appearance frequency. The compression device 15 converts the input symbol into a codeword according to such allocation. That is, the codeword obtained by the conversion is a variable length code. Note that the symbol is, for example, data of a fixed length.

The symbol to be encoded is one of N types of symbols. Hereinafter, a case where N is 286 will be mainly exemplified.

The 286 types of symbols are, for example, 256 1-byte character data (Literal), symbols corresponding to 29 match lengths, and symbols corresponding to one block end. In this case, the 286 types of symbols correspond to values from 0 to 285, respectively. Any value from 0 to 285 corresponding to each of the 286 types of symbols is also referred to as a symbol number. Note that such a number of types of symbols and a value corresponding to each symbol are merely examples, and may be changed according to characteristics of data including a symbol to be encoded.

The compression device 15 includes a code table generation device 32. The code table generation device 32 is a device that generates a code table for converting symbols into variable length codes. The code table generation device 32 may be a device provided in the compression device 15 or may be a part of circuitry that realizes the compression device 15. Hereinafter, the code table generation device 32 is also referred to as a code table generation unit 32.

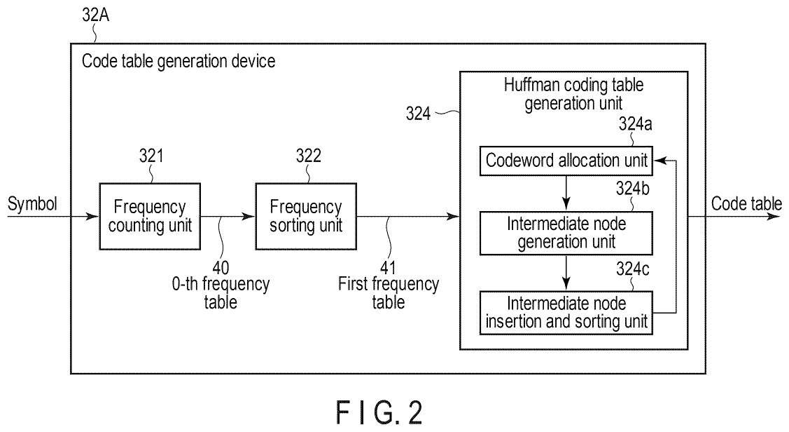

Here, generation of a code table in a code table generation device 32A according to a first comparative example will be described with reference to FIGS. 2 to 6.

FIG. 2 is a block diagram illustrating a configuration of the code table generation device 32A according to the first comparative example. The code table generation device 32A includes, for example, a frequency counting unit 321, a frequency sorting unit 322, and a Huffman coding table generation unit 324.

The frequency counting unit 321 generates a frequency table 40 (hereinafter, it is referred to as a 0-th frequency table 40) using the input symbols. The 0-th frequency table 40 is a table indicating a plurality of symbols and appearance frequencies of the plurality of symbols. The frequency counting unit 321 transmits the 0-th frequency table 40 to the frequency sorting unit 322.

The frequency sorting unit 322 sorts the entries in the 0-th frequency table 40 in descending order of the appearance frequency. The frequency table obtained by sorting is referred to as a first frequency table 41. The frequency sorting unit 322 transmits the first frequency table 41 to the Huffman coding table generation unit 324.

The Huffman coding table generation unit 324 generates the code table using the first frequency table 41. As illustrated in FIG. 2, the Huffman coding table generation unit 324 further includes a codeword allocation unit 324a, an intermediate node generation unit 324b, and an intermediate node insertion and sorting unit 324c.

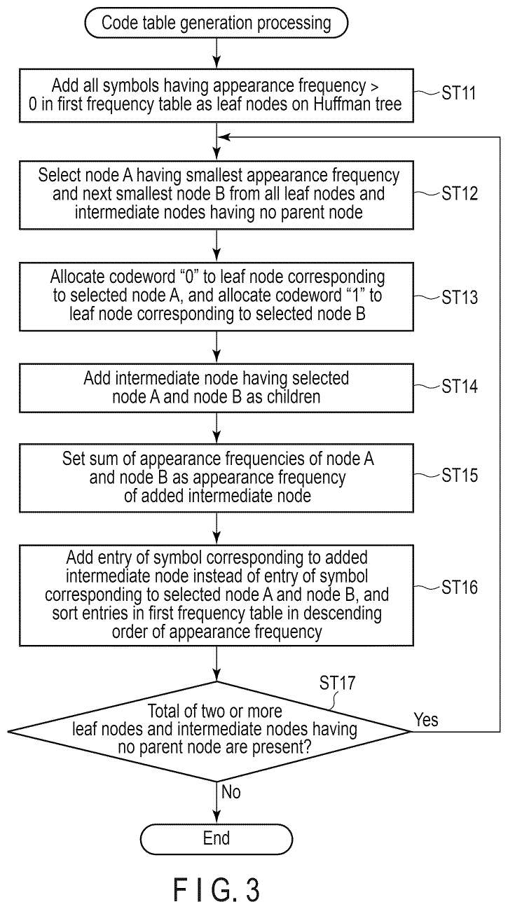

FIG. 3 is a flowchart illustrating an example of a procedure of code table generation processing executed by the Huffman coding table generation unit 324.

First, the Huffman coding table generation unit 324 adds all symbols having an appearance frequency greater than 0 in the first frequency table 41 as leaf nodes on the Huffman tree (step ST11). That is, the Huffman coding table generation unit 324 generates a Huffman tree including leaf nodes corresponding to the number of symbols having an appearance frequency greater than 0 in the first frequency table 41. The number of symbols (that is, the number of leaf nodes of the Huffman tree to be generated) to be subjected to the Huffman tree generation and the codeword allocation by the Huffman coding table generation unit 324 is N at the maximum.

Next, the Huffman coding table generation unit 324 selects the node A having the smallest appearance frequency and the next smallest node B from all the leaf nodes and the intermediate nodes having no parent node in the Huffman tree (step ST12).

Subsequently, the codeword allocation unit 324a of the Huffman coding table generation unit 324 allocates the codeword “0” to the leaf node corresponding to the selected node A, and allocates the codeword “1” to the leaf node corresponding to the selected node B (step ST13). That is, the codeword allocation unit 324a allocates a codeword “0” to a leaf node (symbol) corresponding to one node having a smaller appearance frequency among the two selected nodes, and allocates a codeword “1” to a leaf node (symbol) corresponding to the other node. However, the allocation method of a codeword is not limited thereto, and for example, the codeword allocation unit 324a may allocate a codeword “1” to a leaf node corresponding to one node having a smaller appearance frequency among the two selected nodes, and may allocate a codeword “0” to a leaf node corresponding to the other node.

Thereafter, the intermediate node generation unit 324b of the Huffman coding table generation unit 324 generates an intermediate node having the selected node A and the node B as children, and adds the intermediate node to the Huffman tree (step ST14). Then, the intermediate node generation unit 324b sets the sum of the appearance frequencies of the node A and the node B as the appearance frequency of the added intermediate node (step ST15).

The intermediate node insertion and sorting unit 324c of the Huffman coding table generation unit 324 inserts (adds) an entry of a symbol corresponding to the added intermediate node (that is, the entry indicating the symbol corresponding to the intermediate node and the appearance frequency of the intermediate node) into the first frequency table 41 instead of the entry of the symbol corresponding to the selected node A and node B, and sorts the entries in the first frequency table 41 in descending order of the appearance frequency (step ST16).

Thereafter, the Huffman coding table generation unit 324 determines whether a total of two or more leaf nodes and intermediate nodes having no parent node are present in the Huffman tree (step ST17). This processing corresponds to processing of determining whether there are two or more entries in the first frequency table 41.

In the processing of step ST17, in a case where there are two or more leaf nodes and intermediate nodes having no parent node in the Huffman tree, in other words, in a case where there are two or more entries in the first frequency table 41 (Yes in step ST17), the Huffman coding table generation unit 324 executes the processing of step ST12 again.

On the other hand, in the processing of step ST17, in a case where the number of leaf nodes and intermediate nodes having no parent node in the Huffman tree is less than two, in other words, in a case where there is one entry in the first frequency table 41 (No in step ST17), the Huffman coding table generation unit 324 ends the code table generation processing.

Through the above code table generation processing, the Huffman coding table generation unit 324 can generate a code table (Huffman coding table).

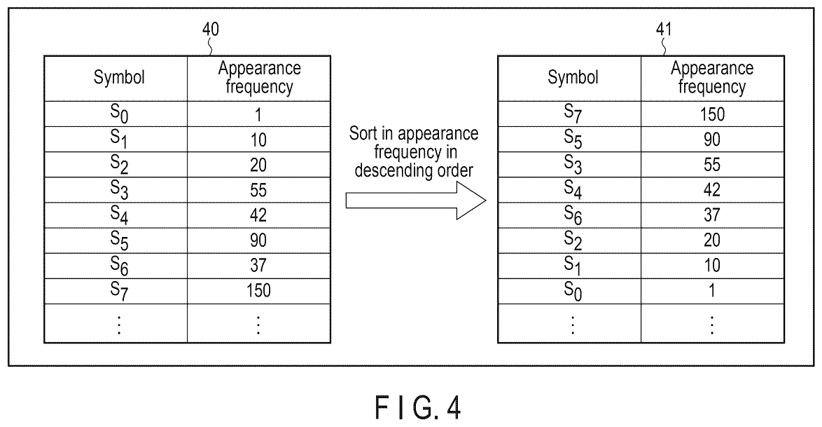

Next, a specific example of the above-described code table generation processing will be described with reference to FIGS. 4 to 6.

FIG. 4 illustrates a configuration example of the 0-th frequency table 40 generated by the frequency counting unit 321 and the first frequency table 41 sorted by the frequency sorting unit 322. Both the 0-th frequency table 40 and the first frequency table 41 include a plurality of entries respectively corresponding to a plurality of symbols. Each of the plurality of entries includes, for example, a symbol field and an appearance frequency field.

The symbol field indicates a corresponding symbol.

The appearance frequency field indicates the appearance frequency of the corresponding symbol. More specifically, the appearance frequency field indicates, for example, the frequency (for example, the number of times) at which the corresponding symbol appears in the input data to be processed.

Note that, hereinafter, the value indicated in the symbol field is also simply referred to as a symbol. The same applies to the values indicated in the other fields of the 0-th frequency table 40 and the first frequency table 41 and the values indicated in the fields of the other tables.

In the example illustrated in FIG. 4, the appearance frequency of the symbol “S₇” is 150. The appearance frequency of the symbol “S₅” is 90. The appearance frequency of the symbol “S₃” is 55. The appearance frequency of the symbol “S₄” is 42. The appearance frequency of the symbol “S₆” is 37. The appearance frequency of the symbol “S₂” is 20. The appearance frequency of the symbol “S₁” is 10. The appearance frequency of the symbol “S₀” is 1.

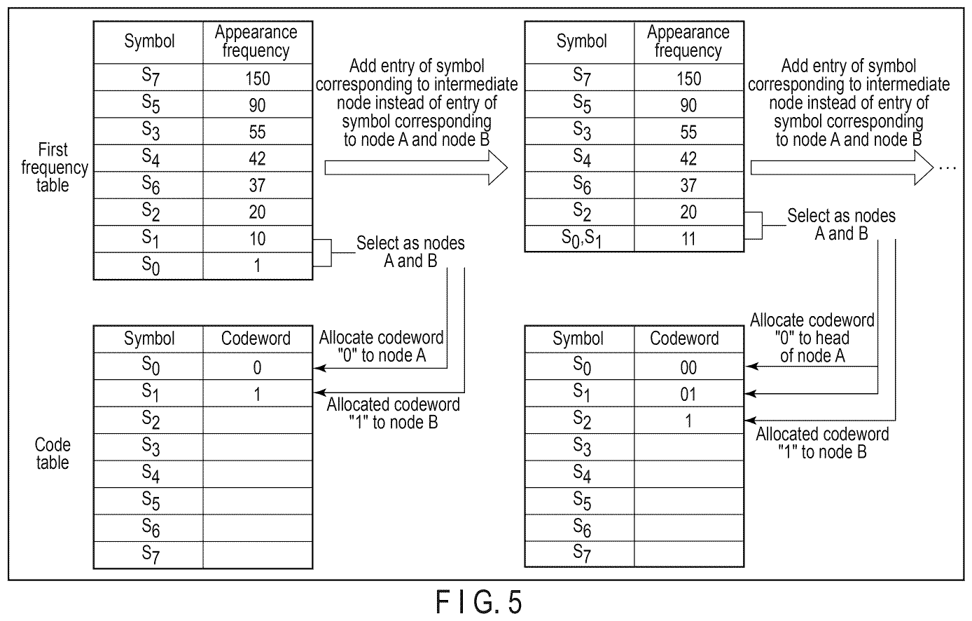

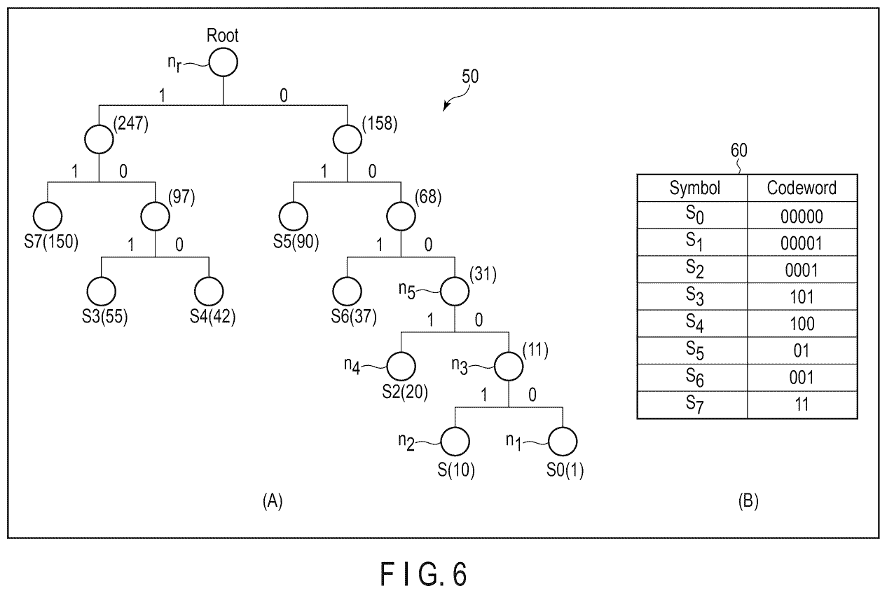

FIG. 5 and FIG. 6 are diagrams for specifically describing the processing of steps ST12 to ST16 illustrated in FIG. 3. Here, a case where the code table is generated using the first frequency table 41 illustrated in FIG. 4 will be described.

First, the Huffman coding table generation unit 324 selects the symbol “S₀” corresponding to the entry having the smallest appearance frequency as the node A from the first frequency table 41 (in other words, a node n₁ in FIG. 6(A) is selected as the node A), and selects the symbol “S₁” corresponding to the next smallest entry as the node B (in other words, a node n₂ in FIG. 6(A) is selected as the node B).

Next, the codeword allocation unit 324a of the Huffman coding table generation unit 324 allocates a codeword “0” to the symbol “S₀” corresponding to the selected node A, and allocates a codeword “1” to the symbol “S₁” corresponding to the selected node B.

Subsequently, the intermediate node generation unit 324b of the Huffman coding table generation unit 324 generates an intermediate node (node n₃ in FIG. 6(A)) obtained by connecting the selected node A and node B, and calculates a sum “11” (=1+10) of 1, which is the appearance frequency of the symbol “S₀” corresponding to the node A, and 10, which is the appearance frequency of the symbol “S₁” corresponding to the node B, as the appearance frequency of the intermediate node.

Thereafter, the intermediate node insertion and sorting unit 324c of the Huffman coding table generation unit 324 adds an entry including symbols “S₀, S₁” corresponding to the generated intermediate node and the calculated appearance frequency “11” to the first frequency table 41 instead of the entry including the symbol “S₀” corresponding to the selected node A and the entry including the symbol “S₁” corresponding to the selected node B.

The intermediate node insertion and sorting unit 324c sorts the entries in the new first frequency table 41 including the entries corresponding to the symbols “S₀, S₁” in descending order of the appearance frequency. According to this, the entries corresponding to the symbols “S₀, S₁” are sorted at the end of the first frequency table 41.

Next, the Huffman coding table generation unit 324 selects the symbols “S₀, S₁” corresponding to the entry having the smallest appearance frequency as the node A from the first frequency table 41 (in other words, a node n₃ in FIG. 6(A) is selected as the node A), and selects the symbol “S₂” corresponding to the next smallest entry as the node B (in other words, a node ng in FIG. 6(A) is selected as the node B).

The codeword allocation unit 324a allocates “O” to the heads of the codewords associated with the symbols “S₀” and “S₁” corresponding to the selected node A (that is, the codeword of the symbol “S₀” becomes “00”, and the codeword of the symbol “S₁” becomes “01”), and allocates the codeword “1” to the symbol “S₂” corresponding to the selected node B.

Subsequently, the intermediate node generation unit 324b generates an intermediate node (node n₅ in FIG. 6(A)) obtained by connecting the selected node A and the node B, and calculates a sum “31” (=11+20) of 11, which is the appearance frequency of the symbols “S₀, S₁” corresponding to the node A and 20, which is the appearance frequency of the symbol “S₂” corresponding to the node B as the appearance frequency of the intermediate node.

Thereafter, the intermediate node insertion and sorting unit 324c adds an entry including the symbols “S₂, (S₀, S₁)” corresponding to the generated intermediate node and the calculated appearance frequency “31” to the first frequency table 41 instead of the entry including the symbols “S₀, S₁” corresponding to the selected node A and the entry including the symbol “S₂” corresponding to the selected node B.

The intermediate node insertion and sorting unit 324c sorts the entries in the new first frequency table 41 including the entries corresponding to the symbols “S₂, (S₀, S₁)” in descending order of the appearance frequency. According to this, the entries corresponding to the symbols “S₂, (S₀, S₁)” are sorted at the end of the first frequency table 41.

Thereafter, similar processing is repeatedly executed until the number of entries in the first frequency table 41 becomes one (in other words, the processing is repeatedly executed until the node having no parent node becomes only a root node nr in FIG. 6(A)). Therefore, while constructing a Huffman tree 50 in FIG. 6(A), the Huffman coding table generation unit 324 can generate a code table 60 in FIG. 6(B).

However, in the code table generation device 32A according to the first comparative example, the processing of generating the code table 60 while constructing the Huffman tree 50 requires the processing amount proportional to the type of the appeared symbol. Therefore, in the code table generation device 32A according to the first comparative example, in a case where there are many types of symbols that have appeared, it takes a lot of time to process the code table generation, or the circuit scale (for example, the number of gates) of the code table generation device 32A increases to complete the code table generation within a specific time.

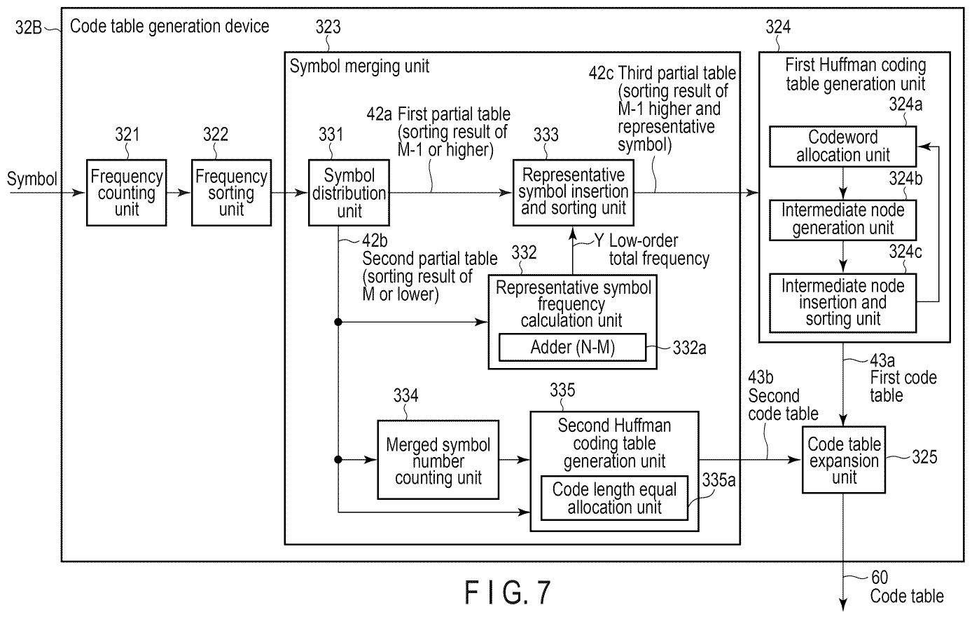

For this reason, a code table generation device 32B that can reduce the amount of processing for generating a code table has been devised. Hereinafter, the generation of the code table in the code table generation device 32B according to the second comparative example will be described with reference to FIGS. 7 to 10.

FIG. 7 is a block diagram illustrating a configuration of the code table generation device 32B according to the second comparative example. In the following description, the same reference numerals are given to the same configurations as those illustrated in FIG. 2, and a detailed description thereof will be omitted.

The code table generation device 32B includes, for example, the frequency counting unit 321, the frequency sorting unit 322, a symbol merging unit 323, the first Huffman coding table generation unit 324, and a code table expansion unit 325. Note that the first Huffman coding table generation unit 324 has a configuration similar to that of the Huffman coding table generation unit 324 illustrated in FIG. 2, and further includes the codeword allocation unit 324a, the intermediate node generation unit 324b, and the intermediate node insertion and sorting unit 324c.

When generating the code table 60, the symbol merging unit 323 performs processing for regarding one or more symbols having a low appearance frequency among all symbols (that is, N symbols) included in the first frequency table 41 as one symbol (hereinafter, referred to as a representative symbol). The symbol merging unit 323 includes, for example, a symbol distribution unit 331, a representative symbol frequency calculation unit 332, a representative symbol insertion and sorting unit 333, a merged symbol number counting unit 334, and a second Huffman coding table generation unit 335.

The symbol distribution unit 331 divides the first frequency table 41 into a first partial table 42a and a second partial table 42b.

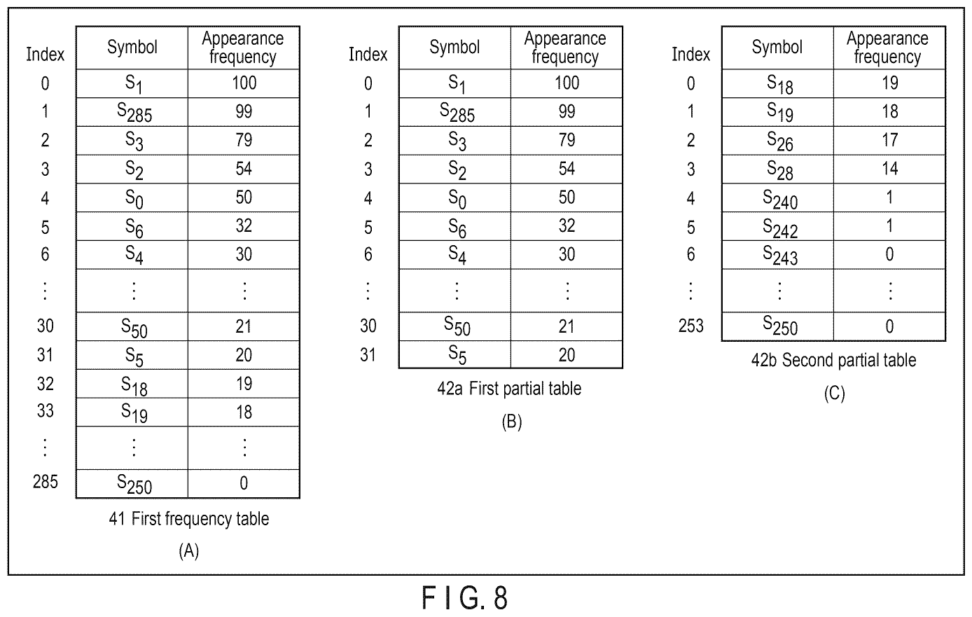

Here, the first frequency table 41, the first partial table 42a, and the second partial table 42b will be described in detail with reference to FIG. 8.

FIG. 8(A) illustrates an example of the first frequency table 41. The first frequency table 41 illustrated in FIG. 8(A) includes N entries respectively corresponding to N types of symbols, and is a table in which the N entries are sorted in descending order of appearance frequency. The first frequency table 41 illustrated in FIG. 8(A) includes a symbol field and an appearance frequency field similarly to the first frequency table 41 illustrated in FIG. 4. An index from 0 to N−1 is assigned to each of N entries in the first frequency table 41 in order from the head. Therefore, each of the N entries can be specified by an index. In the example illustrated in FIG. 8, N is 286, and indexes from 0 to 285 are given.

In the first frequency table 41 illustrated in FIG. 8(A), for example, an entry with an index of 0 indicates that the appearance frequency of the symbol S₁ is 100. For example, an entry whose index is 1 indicates that the appearance frequency of a symbol S285 is 99. In addition, an entry whose index is 285 indicates that the appearance frequency of a symbol S₂₅₀ is 0.

As described above, in the first frequency table 41, 286 entries are arranged in descending order of appearance frequency.

FIG. 8(B) illustrates an example of the first partial table 42a divided from the first frequency table 41 illustrated in FIG. 8(A), and FIG. 8(C) illustrates an example of the second partial table 42b divided from the first frequency table 41 illustrated in FIG. 8(A). In the example illustrated in FIG. 8, N is 286, and M to be described later is 33.

The first partial table 42a includes entries ranked M−1 or higher in descending order of appearance frequency among the N entries included in the first frequency table 41. On the other hand, the second partial table 42b includes entries ranked M or lower in descending order of appearance frequency among the N entries included in the first frequency table 41. M is an integer of 3 or more and less than N.

That is, as illustrated in FIG. 8(B), the first partial table 42a includes top (M−1) entries in descending order of the appearance frequency among the N entries included in the first frequency table 41.

The (M−1) entries are (M−1) entries having a high appearance frequency, and the (M−1) symbols having a high appearance frequency may be referred to as high-order symbols. Note that, as illustrated in FIG. 8(B), indexes from 0 to M−2 (in this case, 0 to 31) are respectively assigned to the (M−1) entries in the first partial table 42a in order from the head.

On the other hand, as illustrated in FIG. 8(C), the second partial table 42b includes the remaining (N−M+1) entries obtained by excluding the high-order (M−1) entries from the N entries included in the first frequency table 41. The (N−M+1) entries are (N−M+1) entries having a low appearance frequency, and the (N−M+1) symbols having a low appearance frequency may be referred to as low-order symbols. The (N−M+1) low-order symbols are regarded as one representative symbol when the code table is generated. That is, the representative symbol is a symbol representing (N−M+1) low-order symbols. Note that, as illustrated in FIG. 8(C), indexes from 0 to N−M (in this case, 0 to 253) are respectively assigned to (N−M+1) entries in the second partial table 42b in order from the head.

The description returns to FIG. 7.

The symbol distribution unit 331 transmits the first partial table 42a to the representative symbol insertion and sorting unit 333. In addition, the symbol distribution unit 331 transmits the second partial table 42b to the representative symbol frequency calculation unit 332, the merged symbol number counting unit 334, and the second Huffman coding table generation unit 335.

When generating the code table 60, the representative symbol frequency calculation unit 332 calculates the appearance frequency of the representative symbol in order to regard (N−M+1) low-order symbols included in the second partial table 42b as one representative symbol. The appearance frequency of the representative symbol is the sum of the appearance frequencies of (N−M+1) low-order symbols, and is calculated using, for example, (N−M) adders 332a arranged in a tree shape. The calculated appearance frequency of the representative symbol is sent to the representative symbol insertion and sorting unit 333. Note that the appearance frequency of the representative symbol is a sum of the appearance frequencies of the low-order symbols, and may be referred to as a low-order total frequency Y.

The representative symbol insertion and sorting unit 333 inserts (adds) an entry (that is, the entry corresponding to the representative symbol) including the appearance frequency of the representative symbol transmitted by the representative symbol frequency calculation unit 332 into the first partial table 42a sent by the symbol distribution unit 331, and sorts the entries in the first partial table 42a in descending order of the appearance frequency.

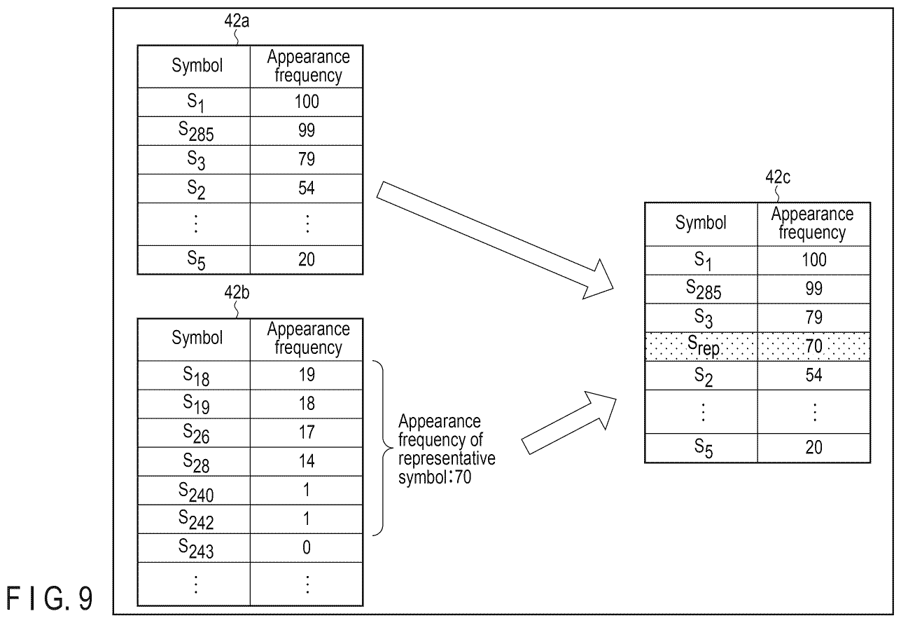

Here, the representative symbol insertion and sorting unit 333 will be described in detail with reference to FIG. 9. FIG. 9 assumes a case where the first partial table 42a illustrated in FIG. 8(B) is input to the representative symbol insertion and sorting unit 333, and a value “70” calculated using the second partial table 42b illustrated in FIG. 8(C) is input to the representative symbol insertion and sorting unit 333 as the appearance frequency of the representative symbol.

In this case, the representative symbol insertion and sorting unit 333 inserts (adds) an entry including a symbol “Sᵣₑₚ” and the appearance frequency “70” into the first partial table 42a as an entry corresponding to the input representative symbol including the appearance frequency of the representative symbol, and sorts the entries (that is, M entries including upper (M−1) entries and one entry corresponding to the representative symbol) in the first partial table 42a in descending order of the appearance frequency. In the example of FIG. 9, the entries corresponding to the symbol “Sᵣₑₚ” (that is, the entry corresponding to the representative symbol) are sorted fourth from the top. A frequency table obtained by inserting entries corresponding to the representative symbols and sorting the entries is referred to as a third partial table 42c. The representative symbol insertion and sorting unit 333 transmits the third partial table 42c to the first Huffman coding table generation unit 324.

The description returns to FIG. 7.

The first Huffman coding table generation unit 324 executes code table generation processing using the third partial table 42c sent by the representative symbol insertion and sorting unit 333. Specifically, among the M symbols (more specifically, (M−1) symbols and 1 representative symbol) included in the third partial table 42c, each symbol having an appearance frequency greater than 0 is arranged as a leaf node, and the code table generation processing is executed. The code table generation processing is similar to the code table generation processing described above with reference to FIG. 3. Specifically, this code table generation processing is processing in which all symbols having an appearance frequency of greater than 0 in the first frequency table 41 in step ST11 are replaced with all symbols having an appearance frequency of greater than 0 among (M−1) symbols and one representative symbol included in the third partial table 42c in the code table generation processing described above with reference to FIG. 3. The first Huffman coding table generation unit 324 transmits the generated code table to a code table expansion unit 325 as a first code table 43a.

The merged symbol number counting unit 334 counts the number C of symbols having an appearance frequency greater than 0 included in the second partial table 42b. C is an integer of 0 or more. When the second partial table 42b does not include a symbol whose appearance frequency is greater than 0, C is 0. A symbol whose appearance frequency is greater than 0 included in the second partial table 42b is referred to as a merged symbol. The merged symbol is a symbol to which a variable length code needs to be allocated among the symbols included in the second partial table 42b. The number C of merged symbols counted by the merged symbol number counting unit 334 is the number of merged symbols represented by the representative symbol. The merged symbol number counting unit 334 transmits the merged symbol number C to the second Huffman coding table generation unit 335.

The second Huffman coding table generation unit 335 includes a code length equal allocation unit 335a.

The code length equal allocation unit 335a equally allocates the code lengths to C merged symbols having an appearance frequency of greater than 0 among the symbols ranked M or lower (that is, (N−M+1) low-order symbols) included in the second partial table 42b. Specifically, the code lengths are equally allocated by the following procedures (A1) and (A2).

(A1) An integer D satisfying Equation 1 is obtained.

$$D = ⌊ {log}_{2} ( c ) ⌋ \qquad Equation 1$$

(A2) Among the C merged symbols, in ascending order of the appearance frequency in the second partial table 42b (in other words, in descending order of the index), a code length (D+1) is allocated to (2C−2^{D+1}) merged symbols, and a code length D is allocated to the remaining merged symbols (that is, (2^{D+1}−C) merged symbols).

For example, it is assumed that the number of the merged symbols C is five, the five merged symbols are symbols Sₘ₀, Sₘ₁, Sₘ₂, Sₘ₃, and Sₘ₄, and the appearance frequencies of the symbols Sₘ₀, Sₘ₁, Sₘ₂, Sₘ₃, and Sₘ₄ have a relationship of Sₘ₀>Sₘ₁>Sₘ₂>Sₘ₃>Sₘ₄.

In this case, the code length equal allocation unit 335a calculates D=2 as maximum integer D less than or equal to log₂(5) by the above procedure (A1). Then, the code length equal allocation unit 335a allocates a code length 3(=2+1) to two (=(2×5)−2²⁺¹) merged symbols Sₘ₃ and Sₘ₄ having a small appearance frequency among the five merged symbols Sₘ₀, Sₘ₁, Sₘ₂, Sₘ₃, and Sₘ₄, and allocates a code length 2 to the remaining three (=5−2) merged symbols Sₘ₀, Sₘ₁, and Sₘ₂.

The code length equal allocation unit 335a generates a second code table 43b using the code lengths of the C merged symbols. The code length equal allocation unit 335a determines a code bit string (variable length code) to be allocated to the symbol using only the code length of the symbol.

Specifically, the code length equal allocation unit 335a allocates the code bit string to the symbol according to the following rules (B1) and (B2).

(B1) The code bit string allocated to the symbol having the short code length precedes the code bit string allocated to the symbol having the long code length in the dictionary order.

(B2) In any two symbols having the same code length, the code bit string allocated to the preceding symbol in the symbol order precedes the code bit string allocated to the subsequent symbol in the symbol order in the dictionary order.

For example, in order to determine the dictionary order of the code bit string, the dictionary order of the bit values “0” and “1” is defined as the order of “0” and “1”. In this case, the dictionary order of the plurality of code bit strings can be determined by comparing the orders (bit orders) of the corresponding bit values included in the plurality of code bit strings in order from the high-order bit.

More specifically, for example, “1′b0”, “2″b10”, “3′b110”, and “3′b111” are four code bit strings arranged in a dictionary order. Note that a data string of bit values of 0 or 1 subsequent to “X′b” indicates an X-bit data string. Therefore, in these four code bit strings, the bit order of the most significant bit of the 1-bit code bit string “1′b0” precedes the bit order of the 2-bit code bit string “2′b10”. The 2-bit code bit string “2′b10” is preceded by the bit order of the next most significant bit with respect to the 3-bit code bit string “3′b110”. The 3-bit code bit string “3′b110” is preceded by the bit order of the least significant bit with respect to the 3-bit code bit string “3′b111”.

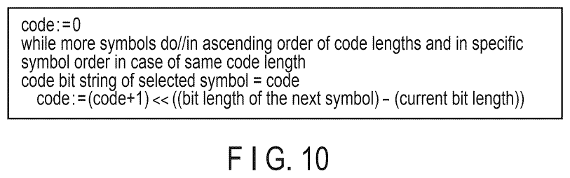

FIG. 10 illustrates an example of the pseudo program for allocating the code bit string to the symbol by the code length equal allocation unit 335a. In the pseudo program, a variable code is used to calculate a code bit string allocated to the symbol.

First, the code length equal allocation unit 335a sets 0(=1′b0) to the code. Note that the number of bits of the code follows the minimum code length among a plurality of code lengths associated with a plurality of symbols to which the code bit string is to be allocated.

Next, in one while loop, the code length equal allocation unit 335a determines the code bit string to be allocated to one symbol in the ascending order of the code lengths and in the specific symbol order in the case of the same code length.

For example, in the first while loop, the code length equal allocation unit 335a selects, as a target for allocation of a code bit string, a symbol having the shortest code length and in a case where there is another symbol having the same code length, the symbol that precedes in a predetermined symbol order. Then, the code length equal allocation unit 335a allocates code (=1′b0) as a code bit string of the selected symbol. Note that, as described above, the number of bits of the code to be allocated first depends on the minimum code length. In this example, it is assumed that the minimum code length is 1. Then, the code length equal allocation unit 335a performs a shift operation of shifting a value obtained by adding 1 to the code to the left by the number of bits obtained by subtracting the code length of the current symbol from the code length of the next symbol, and sets a value obtained by this shift operation to the code. For example, in a case where the number of bits obtained by subtracting the code length of the current symbol from the code length of the next symbol is 1, a value 2′b10 obtained by shifting 1′b1, which is a value obtained by adding 1 to code (=1′b0), to the left by 1 bit is set to code.

Furthermore, for example, in the second while loop, the code length equal allocation unit 335a selects a symbol having the second shortest code length or, in a case where there is another symbol having the shortest code length and the same code length, the second symbol in the specific symbol order as a target to which the code bit string is allocated. The code length equal allocation unit 335a allocates code (=2′b10) as a code bit string of the selected symbol. Then, the code length equal allocation unit 335a performs a shift operation of shifting a value obtained by adding 1 to the code to the left by the number of bits obtained by subtracting the code length of the current symbol from the code length of the next symbol, and sets a value obtained by this shift operation to the code. For example, in a case where the number of bits obtained by subtracting the code length of the current symbol from the code length of the next symbol is 1, a value 3′b110 obtained by shifting 2′b11, which is a value obtained by adding 1 to code (=2′b10), to the left by 1 bit is set to code.

By performing such loop processing, the code length equal allocation unit 335a can allocate the code bit string to each of the plurality of symbols by using the order relation between the symbols and the plurality of code lengths corresponding to the plurality of symbols. That is, the code length equal allocation unit 335a can uniquely determine the code bit string to be allocated to each symbol by determining the order relation between the symbols and the code length of each symbol.

For example, in a case where the code lengths of the merged symbols Sₘ₃ and Sₘ₄ are 3 and the code lengths of the merged symbols Sₘ₀, Sₘ₁, and Sₘ₂ are 2 as the code lengths of the C merged symbols, the code length equal allocation unit 335a, in a first while loop, first selects, as a target for allocating a code bit string, the symbol Sₘ₀ that comes first in index order among the symbols Sₘ₀, Sₘ₁, and Sₘ₂ having the shortest code length. Then, the code length equal allocation unit 335a allocates code (=2′b00) as a code bit string of the selected symbol Sₘ₀. Thereafter, the code length equal allocation unit 335a performs a shift operation of shifting a value obtained by adding 1 to the code to the left by the number of bits obtained by subtracting the code length of the current symbol from the code length of the next symbol, and sets a value obtained by this shift operation to the code. In this case, since the number of bits obtained by subtracting 2 that is the code length of the current symbol from 2 that is the code length of the next symbol Sₘ₁ is 0, 2′b01 that is a value obtained by shifting 2′b01, which is a value obtained by adding 1 to code (=2′b00), to the left by 0 bits (that is, the value as it is) is set as code.

Thereafter, in the second while loop, the code length equal allocation unit 335a selects the second symbol Sₘ₁ in the index order among the symbols Sₘ₀, Sₘ₁, and Sₘ₂ having the shortest code length as a target to which the code bit string is allocated. The code length equal allocation unit 335a allocates the set code (=2′b01) as a code bit string of the selected symbol Sₘ₁. Thereafter, the code length equal allocation unit 335a performs a shift operation of shifting a value obtained by adding 1 to the code to the left by the number of bits obtained by subtracting the code length of the current symbol from the code length of the next symbol, and sets a value obtained by this shift operation to the code. In this case, since the number of bits obtained by subtracting 2 that is the code length of the current symbol from 2 that is the code length of the next symbol Sₘ₂ is 0, 2′b10 that is a value obtained by shifting 2′b10, which is a value obtained by adding 1 to code (=2′b01), to the left by 0 bits (that is, the value as it is) is set as code.

Thereafter, by performing similar loop processing, the code length equal allocation unit 335a can generate the second code table 43b in which the codeword “00” is allocated to the merged symbol Sₘ₀, the codeword “01” is allocated to the merged symbol Sₘ₁, the codeword “10” is allocated to the merged symbol Sₘ₂, the codeword “110” is allocated to the merged symbol Sₘ₃, and the codeword “111” is allocated to the merged symbol Sₘ₄.

The code length equal allocation unit 335a (second Huffman coding table generation unit 335) transmits the generated second code table 43b to the code table expansion unit 325.

The code table expansion unit 325 expands the second code table 43b transmitted by the second Huffman coding table generation unit 335 as a suffix of a codeword corresponding to the representative symbol Sᵣₑₚ included in the first code table 43a transmitted by the first Huffman coding table generation unit 324, and generates (acquires) the code table 60.

For example, in a case where the codeword allocated to the representative symbol Sᵣₑₚ in the first code table 43a is “0010” and the codeword allocated to the symbol Sₘ₀ in the second code table 43b is “00”, the code table expansion unit 325 acquires a codeword “001000” obtained by expanding the codeword “00” allocated in the second code table 43b at the end of the codeword “0010” of the representative symbol Sᵣₑₚ as the codeword for the symbol Sₘ₀.

In addition, in a case where the codeword allocated to the representative symbol Sᵣₑₚ in the first code table 43a is “0010” and the codeword allocated to the symbol Sₘ₁ in the second code table 43b is “01”, the code table expansion unit 325 acquires a codeword “001001” obtained by expanding the codeword “01” allocated in the second code table 43b at the end of the codeword “0010” of the representative symbol as the codeword for the symbol Sₘ₁.

By performing similar processing on each symbol included in the second code table 43b, it is possible to generate (acquire) the code table 60 in which codewords are allocated to all symbols having an appearance frequency greater than 0 among the N types of symbols.

In the code table generation device 32B according to the second comparative example, while the codeword is allocated to the representative symbol in which the high-order symbols ranked (M−1) or higher and the low-order symbols ranked M or lower are integrated by the code table generation processing illustrated in FIG. 3, the code length is equally allocated to the low-order symbols ranked M or lower, and the codeword is allocated using the equally allocated code length (that is, the codeword is simply allocated).

According to this, in the code table generation device 32A according to the first comparative example described above, it is necessary to allocate the codeword to the maximum N symbols by the code table generation processing illustrated in FIG. 3 described above, whereas in the code table generation device 32B according to the second comparative example, it is sufficient if the codeword is allocated to the maximum M symbols by the code table generation processing illustrated in FIG. 3 described above. For example, in a case where N is 286 and M is 33, in the code table generation device 32B of the second comparative example, the number of symbols to be subjected to the code table generation processing illustrated in FIG. 3 described above is greatly reduced from 286 at the maximum to 33 at the maximum as compared with the code table generation device 32A of the first comparative example. As a result, in the code table generation device 32B of the second comparative example, it is possible to reduce the time required for the code table generation processing or to reduce the circuit scale (for example, the number of gates) for completing the code table generation within a specific time.

In addition, in the code table generation device 32B according to the second comparative example, the codeword is allocated to (M−1) high-order symbols occupying most of the appearance frequency by the code table generation processing illustrated in FIG. 3 described above. Therefore, it is possible to minimize the decrease in the coding efficiency of the dynamic Huffman coding due to the allocation of the codeword in a simplified manner. From the viewpoint of the coding efficiency of the dynamic Huffman coding, M is desirably set to a value smaller than N/2.

However, in the code table generation device 32B according to the second comparative example, in order to generate the code table 60, it is necessary to calculate the appearance frequency (low-order total frequency Y) of the representative symbol obtained by combining the low-order symbols into one, and in order to calculate the low-order total frequency Y, (N−M) adders arranged in a tree shape are required as described above. For example, in a case where N is 286 and M is 33, 253 (=286−33) adders (also referred to as an 8-stage adder tree) arranged in a tree shape are required to calculate the low-order total frequency Y, and the circuit scale increases.

Therefore, the code table generation device 32 according to the present embodiment does not directly calculate the low-order total frequency Y but indirectly calculates the low-order total frequency Y, thereby reducing the circuit scale necessary for calculating the low-order total frequency Y. Specifically, the code table generation device 32 according to the present embodiment calculates a frequency sum Z that is the sum of the frequencies of all the input symbols and a high-order total frequency X that is the sum of the appearance frequencies of the high-order symbols, and calculates the low-order total frequency Y by subtracting the high-order total frequency X from the frequency sum Z.

As described above, (N−M) adders arranged in a tree shape are required to calculate the low-order total frequency Y, whereas (M−2) adders arranged in a tree shape are sufficient to calculate the high-order total frequency X. For example, in a case where N is 286 and M is 33, 253 adders arranged in a tree shape are required to calculate the low-order total frequency Y, whereas 31 (=33-2) adders arranged in a tree shape (also referred to as a 5-stage adder tree) are sufficient to calculate the high-order total frequency X.

In addition, the frequency sum Z can be calculated by counting the frequency of the symbol input to the code table generation device 32 regardless of the type of the symbol and obtaining the sum of the results of the counting. As will be described in detail later, the frequency sum Z is obtained by counting only the frequency (0 or 1) of the symbols input to the code table generation device 32, if the sum of the results of the count is obtained, and thus, for example, in a case where a maximum of four symbols are input per cycle, the frequency sum Z can be calculated using four 1-bit adders, one 2-bit adder, one (n bits+2 bits) adder, and one n-bit total frequency register.

That is, in a case where N is 286 and M is 33, the number of adders required to calculate the high-order total frequency X is 31, the number of adders and registers required to calculate the frequency sum Z is 7, and even if one subtractor that subtracts the high-order total frequency X from the frequency sum Z is further added, the low-order total frequency Y can be calculated with a configuration of 40 or less. According to this, it is possible to realize a significant circuit scale reduction as compared with the code table generation device 32B of the second comparative example in which 253 adders are required to calculate the low-order total frequency Y.

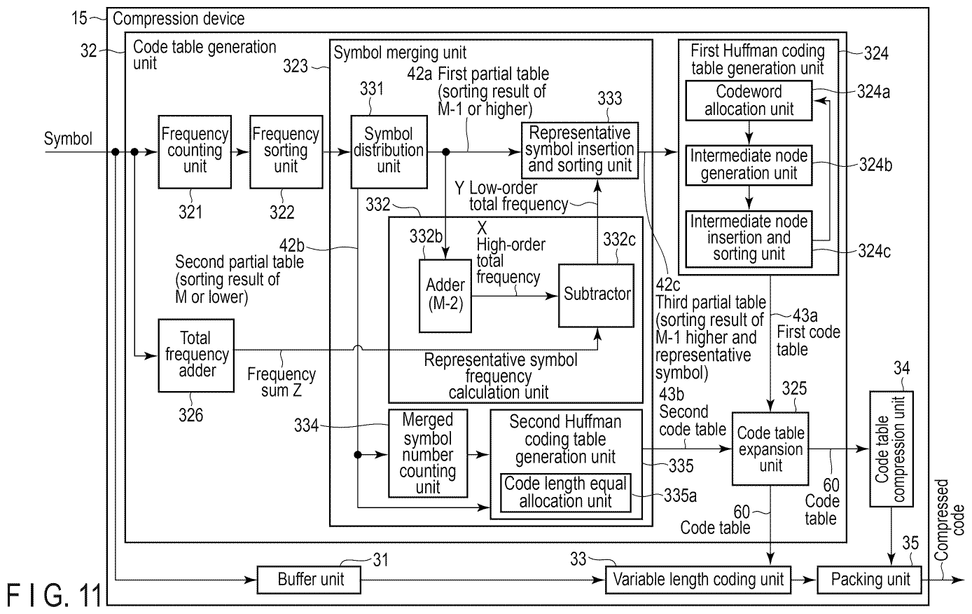

FIG. 11 illustrates a configuration example of the compression device 15 according to the present embodiment. The compression device 15 includes, for example, a buffer unit 31, the code table generation unit 32 (code table generation device 32), a variable length coding unit 33 (coding circuitry), a code table compression unit 34, and a packing unit 35.

The buffer unit 31 stores (buffers) the symbol input to the compression device 15. The buffer unit 31 delays the stored symbols, for example, until a specific timing, and transmits them to the variable length coding unit 33.

The code table generation unit 32 generates the code table 60 using the symbols input to the compression device 15. The code table 60 includes information indicating a plurality of symbols and a plurality of variable length codes (that is, a plurality of code bit strings) associated with the plurality of symbols.

More specifically, the code table generation unit 32 generates the code table 60 based on the appearance frequencies of the plurality of symbols included in the input data of the specific unit. The specific unit may be a specific data amount unit or may be a specific group such as a file. In the case that the unit is the specific group, the code table generation unit 32 recognizes the input data of the specific unit by detecting the data indicating the termination of the input data.

The code table generation unit 32 transmits the generated code table 60 to the variable length coding unit 33 and the code table compression unit 34.

The code table compression unit 34 compresses the code table 60. The code table compression unit 34 transmits the compressed code table 60 to the packing unit 35.

The variable length coding unit 33 converts the symbol transmitted from the buffer unit 31 into the variable length code (code bit string) using the code table 60 transmitted from the code table generation unit 32. The variable length coding unit 33 transmits the variable length code obtained by the conversion to the packing unit 35.

The packing unit 35 sequentially concatenates one or more variable length codes output from the variable length coding unit 33, and outputs the code as the compressed data (compressed stream) of each specific data size. The specific data size is, for example, 64 bits. Further, the packing unit 35 inserts the compressed code table 60 output from the code table compression unit 34 as a header of the compressed data. The compressed code table 60 is used to restore the code table 60 (decoding table) when the compressed data is decoded in a decompressor.

With the above configuration, the compression device 15 can perform the dynamic Huffman coding on the input symbol to convert the input symbol into the variable length code. For example, in a case where the input symbol is data requested to be written to the NAND flash memory 5 by the host 2, the CPU 12 writes the compressed data including one or more variable length codes and the compressed code table 60 to the NAND flash memory 5 via the NAND I/F 13.

In addition, the memory controller 4 may further include an ECC encoder and an ECC decoder. In this case, the ECC encoder generates parity for error correction (ECC parity) for the compressed data output from the packing unit 35, and generates a codeword having the generated ECC parity and the compressed data. Then, the CPU 12 is configured to write the codeword to the NAND flash memory 5 via the NAND I/F 13. That is, the CPU 12 is configured to write data based on the compressed data output from the compression device 15 to the NAND flash memory 5 via the NAND I/F 13. In addition, in a case of receiving a read command from the host 2 via the host I/F 11, for example, the CPU 12 reads out data based on the read command from the NAND flash memory 5 via the NAND I/F 13. The ECC decoder executes error correction processing on the read data. The read data subjected to the error correction processing is input to the decompressor by the CPU 12 as the compressed data, and the decompressor decompresses the input compressed data. The CPU 12 transmits the decompressed data to the host 2 in response to the read command from the host 2. That is, in response to the read command from the host 2, the CPU 12 is configured to decompress data based on data read from the NAND flash memory 5 and transmit the decompressed data to the host 2.

Note that a part or all of the compression device 15 may be realized as, for example, hardware such as a register, a memory, an adder, a multiplier, a selector, and other arithmetic units, or may be realized as a program (that is, software) executed by at least one processor. The register is realized by, for example, order circuitry such as a flip-flop. The memory is realized by, for example, a storage element such as SRAM or DRAM. The adder, the multiplier, the selector, and other arithmetic units are realized by, for example, combinational logic circuitry.

Next, a specific configuration of the code table generation unit 32 will be described. Hereinafter, a configuration having a function similar to that of the configuration illustrated in FIG. 7 will not be described, and a configuration having a function different from that of the configuration illustrated in FIG. 7 will be mainly described.

The code table generation unit 32 includes, for example, the frequency counting unit 321, the frequency sorting unit 322 (first sorting unit), the symbol merging unit 323, the first Huffman coding table generation unit 324, the code table expansion unit 325, and a total frequency addition unit 326. Similarly to the configuration illustrated in FIG. 7, the symbol merging unit 323 includes the symbol distribution unit 331, the representative symbol frequency calculation unit 332, the representative symbol insertion and sorting unit 333 (second sorting unit), the merged symbol number counting unit 334, and the second Huffman coding table generation unit 335. In addition, similarly to the configuration illustrated in FIG. 7, the first Huffman coding table generation unit 324 includes the codeword allocation unit 324a, the intermediate node generation unit 324b, and the intermediate node insertion and sorting unit 324c.

The frequency counting unit 321 generates the 0-th frequency table 40 based on the appearance frequency of the input symbol for each symbol. For example, the frequency counting unit 321 counts the number of appearances of the input symbol for each symbol to generate the 0-th frequency table 40. The frequency counting unit 321 transmits the 0-th frequency table 40 to the frequency sorting unit 322 every time a certain number of cycles T (certain period) elapses. For example, in a case where a maximum of 4 symbols are input to the frequency counting unit 321 per cycle, the number of cycles T may be 1024 cycles. In this case, the frequency counting unit 321 transmits the 0-th frequency table 40 to the frequency sorting unit 322 every time when 4096 symbols are input.

The total frequency addition unit 326 counts the frequency of the input symbol regardless of the type of symbol, and calculates the frequency sum Z which is the sum of the results of the counting. The total frequency addition unit 326 transmits the frequency sum Z to a representative symbol frequency calculation unit 332 of the symbol merging unit 323 every time a certain number of cycles T (certain period) elapses. For example, in a case where the maximum of 4 symbols per cycle are input to the total frequency addition unit 326, the above-described number of cycles T may be 1024 cycles. In this case, every time when 4096 symbols are input, the total frequency addition unit 326 transmits the frequency sum Z to the representative symbol frequency calculation unit 332 of the symbol merging unit 323. The total frequency addition unit 326 may be referred to as a frequency sum calculation unit.

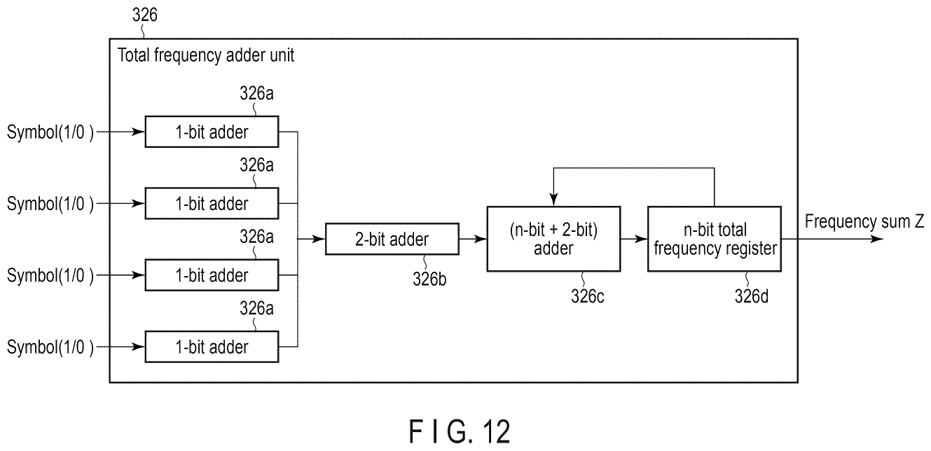

Here, a circuit configuration of the total frequency addition unit 326 will be described with reference to FIG. 12.

FIG. 12 is a block diagram illustrating an example of a circuit configuration of the total frequency addition unit 326. As described above, the total frequency addition unit 326 includes four 1-bit adders 326a, one 2-bit adder 326b, one (n-bit+2-bit) adder 326c, and one n-bit total frequency register 326d.

Each of the four 1-bit adders 326a receives a symbol indicating “1” or “0” as an appearance frequency, and each of the four 1-bit adders 326a outputs a value (That is, “1” or “0”) of the appearance frequency of the input symbol to the 2-bit adder 326b.

The 2-bit adder 326b adds the four inputs from the four 1-bit adders 326a, and outputs a value indicating a result of the addition to the (n-bit+2-bit) adder 326c.

The (n-bit+2-bit) adder 326c adds the value of the current frequency sum Z stored in the n-bit total frequency register 326d to the input from the 2-bit adder 326b, and stores a value indicating a result of the addition in the n-bit total frequency register 326d as a new frequency sum Z.

Note that the above-described n is set to a value that satisfies “P×T≤2ⁿ” defined by the maximum number P of symbols input per cycle and the above-described number of cycles T. For example, in a case where the maximum number P of symbols input per cycle is 4 and the number of cycles T is 1024 cycles, the described above n is set to “12”.

The description returns to FIG. 11.

The symbol distribution unit 331 of the symbol merging unit 323 divides the first frequency table 41 sent by the frequency sorting unit 322 into the first partial table 42a and the second partial table 42b. The symbol distribution unit 331 transmits the first partial table 42a to the representative symbol frequency calculation unit 332 and the representative symbol insertion and sorting unit 333, and transmits the second partial table 42b to the merged symbol number counting unit 334 and the second Huffman coding table generation unit 335.

The representative symbol frequency calculation unit 332 calculates the high-order total frequency X, which is the sum of the appearance frequencies of the symbol ranked (M−1) or higher among the N types of symbols input to the code table generation unit 32, using the first partial table 42a transmitted by the symbol distribution unit 331. The high-order total frequency X is calculated using, for example, (M−2) adders 332b arranged in a tree shape. The adder 332b may be referred to as the high-order total frequency calculation unit.

In addition, the representative symbol frequency calculation unit 332 calculates the low-order total frequency Y, which is the sum of the appearance frequencies of the symbols ranked M or lower among the N types of symbols input to the code table generation unit 32, using the calculated high-order total frequency X and the frequency sum Z transmitted by the total frequency addition unit 326. The low-order total frequency Y is calculated by subtracting the high-order total frequency X from the frequency sum Z using a subtractor 332c. The subtractor 332c may be referred to as a low-order total frequency calculation unit. The representative symbol frequency calculation unit 332 transmits the calculated low-order total frequency Y to the representative symbol insertion and sorting unit 333.

According to this, for example, in a case where N is 286 and M is 33, it is possible to calculate the low-order total frequency Y, which is the appearance frequency of the representative symbol, as long as there are 31 adders for calculating the high-order total frequency X, six adders and one register for calculating the frequency sum Z, and one subtractor for subtracting the high-order total frequency X from the frequency sum Z, and it is possible to realize a significant reduction in circuit scale as compared with the code table generation device 32B of the second comparative example in which 253 adders are required for calculating the low-order total frequency Y.

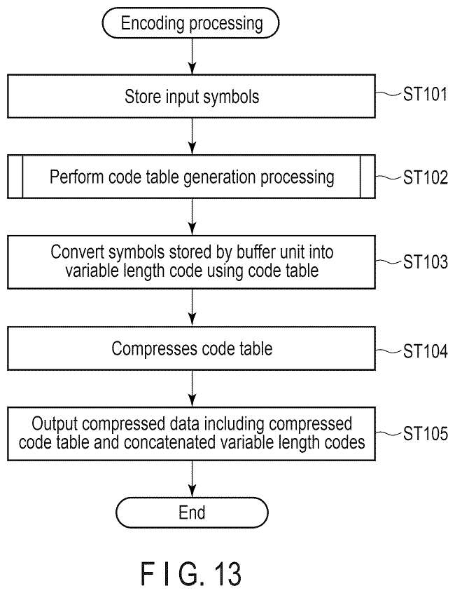

FIG. 13 is a flowchart illustrating an example of a procedure of encoding processing executed in the compression device 15. The encoding processing is processing of converting each of one or more symbols included in data (input data) input to the compression device 15 into a variable length code to acquire the compressed data. The encoding processing is executed, for example, in response to input of data of a specific unit to the compression device 15.

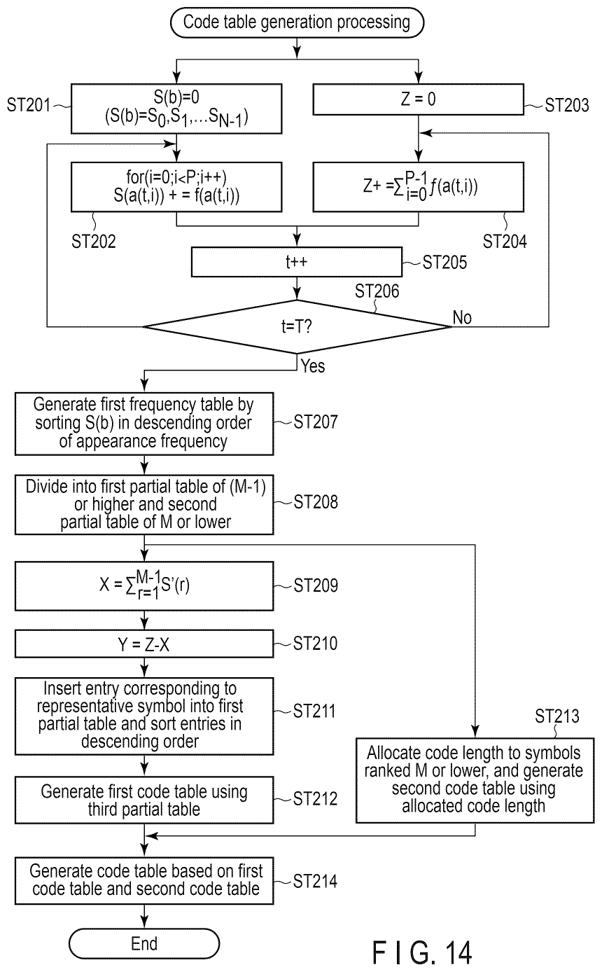

First, the buffer unit 31 stores one or more symbols included in the input data (step ST101). Further, the code table generation unit 32 performs code table generation processing (step ST102). The code table generation processing is processing of generating the code table 60 based on the appearance frequency of one or more symbols included in the input data for each symbol. An example of a specific procedure of the code table generation processing will be described later with reference to a flowchart of FIG. 14. Note that the processing of step ST101 and the processing of step ST102 may be performed in parallel.

Next, using the generated code table 60, the variable length coding unit 33 converts each of one or more symbols stored by the buffer unit 31 into a variable length code (step ST103). Further, the code table compression unit 34 compresses the code table 60 (step ST104). Note that the processing of step ST103 and the processing of step ST104 may be performed in parallel.

The packing unit 35 outputs the compressed data including the compressed code table 60 and the concatenated one or more variable length codes (step ST105), and ends the encoding processing.

As described above, the compression device 15 can convert each of one or more symbols included in the input data into the variable length code to acquire the compressed data. In a case where the input data is, for example, data requested to be written to the NAND flash memory 5 by the host 2, the CPU 12 can write compressed data obtained by compressing the input data to the NAND flash memory 5 via the NAND I/F 13.

FIG. 14 is a flowchart illustrating an example of a procedure of code table generation processing executed in the code table generation unit 32. The code table generation processing corresponds to the processing of step ST102 of the encoding processing described above with reference to FIG. 13. The input data to the compression device 15 is input to the code table generation unit 32.

First, the frequency counting unit 321 initializes the cumulative addition S(b) of N types of symbols for each constant number of cycles T (step ST201). According to this, all the appearance frequencies associated with the respective N types of symbols in the 0-th frequency table 40 are initialized to 0.

The frequency counting unit 321 counts an appearance frequency f(a(t, i)) of an i-th input symbol a(t, i) among the maximum P symbols input in the t-th cycle within the constant number of cycles T (step ST202). The symbol a(t, i) indicates one of N kinds of symbols S₀ to S_{N-1} or null (in other words, there is no symbol input) input to the code table generation unit 32. In addition, the appearance frequency f(a(t, i)) indicates “1” or “0”, and in a case of indicating “1”, the frequency counting unit 321 counts up the appearance frequency (cumulative addition S(b)) of the symbol a(t, i) in the 0-th frequency table 40 by 1.

After the processing of step ST202 is repeatedly executed from i=0 to i=P−1, the frequency counting unit 321 executes processing of step ST205 described later.

While the above-described steps ST201 and ST202 are executed in the frequency counting unit 321, the total frequency addition unit 326 initializes the frequency sum Z stored in the n-bit total frequency register 326d for each constant number of cycles T (step ST203). Accordingly, the value of the frequency sum Z stored in the n-bit total frequency register 326d is initialized to 0. This processing may be performed in parallel with the processing of step ST201.

The total frequency addition unit 326 counts an appearance frequency f(a(t, i)) of an i-th input symbol a(t, i) among the maximum P symbols input in the t-th cycle within the constant number of cycles T, and calculates a sum (frequency sum Z) of the counted appearance frequencies (step ST204). The processing of step ST204 is processing of calculating the sum of the appearance frequencies f(a(t, i)) of the symbols a(t, i) input in each of i=0 to i=P−1. That is, the processing of step ST204 is processing of calculating the sum of the appearance frequencies of all the symbols input in the t-th cycle. This processing may be performed in parallel with the processing of step ST202.

When the processing of steps ST202 and ST204 described above is executed, the frequency counting unit 321 and the total frequency addition unit 326 each add 1 to t (step ST205) and determine whether t after the addition has become T (step ST206).

In the processing of step ST206, in a case where it is determined that t has not become T (No in step ST206), the frequency counting unit 321 returns to step ST202 and repeatedly executes similar processing until t becomes T (that is, until the constant number of cycles T is reached). Similarly, the total frequency addition unit 326 returns to step ST204 and repeatedly executes similar processing until t becomes T (that is, until the constant number of cycles T is reached).

On the other hand, in the processing of step ST206, in a case where it is determined that t has become T (Yes in step ST206), the frequency counting unit 321 transmits the 0-th frequency table 40 generated by repeatedly executing the processing of step ST202 to the frequency sorting unit 322. In addition, the total frequency addition unit 326 transmits the frequency sum Z (that is, the sum of the appearance frequencies of all the symbols input during the certain number of cycles T) calculated by repeatedly executing the processing of step ST204 to the representative symbol frequency calculation unit 332.

The frequency sorting unit 322 sorts the entries (symbols) in the 0-th frequency table 40 transmitted by the frequency counting unit 321 in descending order of the appearance frequency to generate the first frequency table 41 (step ST207). The frequency sorting unit 322 transmits the first frequency table 41 to the symbol merging unit 323.

The symbol distribution unit 331 of the symbol merging unit 323 divides the first frequency table 41 transmitted by the frequency sorting unit 322 into the first partial table 42a including symbols ranked (M−1) or higher and the second partial table 42b including symbols ranked M or lower (step ST208). The symbol distribution unit 331 transmits the first partial table 42a to the representative symbol frequency calculation unit 332 and the representative symbol insertion and sorting unit 333, and transmits the second partial table 42b to the merged symbol number counting unit 334 and the second Huffman coding table generation unit 335.

Note that the processing of steps ST209 to ST212 and the processing of step ST213 may be performed in parallel in the processing subsequent to the processing of step ST208.

The high-order total frequency calculation unit 332b of the representative symbol frequency calculation unit 332 calculates the high-order total frequency X, which is the sum of the appearance frequencies of the symbols ranked (M−1) or higher included in the first partial table 42a transmitted by the symbol distribution unit 331 (step ST209). S′ (r) indicates the appearance frequency corresponding to the symbol ranked r in the first partial table 42a sorted in descending order of the appearance frequency. The high-order total frequency calculation unit 332b transmits the calculated high-order total frequency X to the low-order total frequency calculation unit 332c.

Subsequently, the low-order total frequency calculation unit 332c of the representative symbol frequency calculation unit 332 calculates the low-order total frequency Y by subtracting the high-order total frequency X transmitted by the high-order total frequency calculation unit 332b from the frequency sum Z transmitted by the total frequency addition unit 326 (step ST210). The low-order total frequency calculation unit 332c transmits the calculated low-order total frequency Y to the representative symbol insertion and sorting unit 333.

The representative symbol insertion and sorting unit 333 inserts (adds) an entry of one representative symbol corresponding to the low-order total frequency Y transmitted by the low-order total frequency calculation unit 332c into the first partial table 42a transmitted by the symbol distribution unit 331, and sorts the entries (symbols) in the first partial table 42a after the representative symbol insertion in descending order of the appearance frequency to generate the third partial table 42c (step ST211). The representative symbol insertion and sorting unit 333 transmits the generated third partial table 42c to the first Huffman coding table generation unit 324.

The first Huffman coding table generation unit 324 generates the first code table 43a using the third partial table 42c transmitted by the representative symbol insertion and sorting unit 333 (step ST212). The first Huffman coding table generation unit 324 transmits the generated first code table 43a to the code table expansion unit 325.

Based on the second partial table 42b transmitted by the symbol distribution unit 331 after the processing of step ST208 and the number of merged symbols C transmitted from the merged symbol number counting unit 334, the second Huffman coding table generation unit 335 equally allocates a code length to the symbols ranked M or lower, and generates the second code table 43b corresponding to the symbols ranked M or lower using the allocated code length (step ST213). The second Huffman coding table generation unit 335 transmits the generated second code table 43b to the code table expansion unit 325.

Then, the code table expansion unit 325 expands the codewords corresponding to the symbols ranked M or lower included in the second code table 43b transmitted by the second Huffman coding table generation unit 335 at the end of the codeword corresponding to the representative symbol included in the first code table 43a transmitted by the first Huffman coding table generation unit 324, generates the code table 60 corresponding to all the symbols (that is, N types of symbols) (step ST214), transmits the generated code table 60 to the variable length coding unit 33 and the code table compression unit 34, and ends the code table generation processing.

As described above, the code table generation unit 32 calculates the frequency sum Z and the high-order total frequency X, and calculates the low-order total frequency Y by subtracting the high-order total frequency X from the calculated frequency sum Z. According to this, the circuit scale required for calculating the low-order total frequency Y can be greatly reduced.

In addition, similarly to the code table generation device 32B according to the second comparative example, the code table generation unit 32 can reduce the time required for the code table generation processing or can reduce the circuit scale (for example, the number of gates) for completing the code table generation within a specific time as compared with the code table generation device 32A of the first comparative example.

According to the embodiment described above, it is possible to provide a code table generation device, a memory system, and a code table generation method capable of reducing a processing amount for generating a code table.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A code table generation device comprising
circuitry configured to:
generate a frequency table including a plurality of symbols and a plurality of appearance frequencies respectively associated with the plurality of symbols based on an appearance frequency of each symbol of the symbols input in a certain period;
add all the appearance frequencies of the symbols input in the certain period and calculate a sum of the appearance frequencies of all the symbols input in the certain period;
rearrange the plurality of symbols in descending order of appearance frequency in the frequency table;
acquire a partial table including symbols ranked M−1 or higher from a frequency table including the plurality of rearranged symbols (M is an integer of 3 or higher), and calculate a sum of the appearance frequencies of the symbols ranked M−1 or higher;
subtract the calculated sum of the appearance frequencies of symbols ranked M−1 or higher from the calculated sum of the appearance frequencies of all the symbols and calculate a sum of the appearance frequencies of symbols ranked M or lower in the frequency table including the plurality of rearranged symbols;
add one symbol corresponding to the sum of the appearance frequencies of the symbols ranked M or lower to the partial table, and rearrange the symbols ranked M−1 or higher and the one symbol in descending order of appearance frequency in a partial table after addition;
generate a first code table corresponding to M symbols including the rearranged symbols ranked M−1 or higher and the one symbol;
equally allocate a code length to the symbols ranked M or lower and generate a second code table corresponding to the symbols ranked M or lower using the allocated code length; and
expand, at an end of a codeword corresponding to the one symbol included in the first code table, a codeword corresponding to the symbol ranked M or lower included in the second code table, and generate a code table corresponding to all the symbols.

2. The code table generation device according to claim 1, wherein the circuitry is configured to generate the first code table used for dynamic Huffman coding.

3. The code table generation device according to claim 1, wherein
an appearance frequency of a symbol input in the certain period indicates 1 or 0,
the circuitry is configured to, in a case where an appearance frequency of an input predetermined symbol indicates 1, add 1 to the appearance frequency of the predetermined symbol and add 1 to a sum of appearance frequencies of all the symbols.

4. The code table generation device according to claim 1, wherein the M is set to a value smaller than N/2 in a case where the number of types of the symbols is N (N is an integer of 8 or higher).

5. The code table generation device according to claim 1, wherein the circuitry is configured to equally allocate the code length to C symbols (C is an integer of 0 or higher) having an appearance frequency of greater than 0 among the symbols ranked M or lower.

6. The code table generation device according to claim 1, wherein the sum of the appearance frequencies of the symbols ranked M−1 or higher is calculated using M−2 adders arranged in a tree shape.

7. The code table generation device according to claim 1, wherein
the sum of the appearance frequencies of all the symbols input in the certain period is calculated using n-bit register, and
in a case where the certain period is T cycles and a maximum number of symbols input per cycle is P, the n is set to a value that satisfies P×T≤2ⁿ.

8. A memory system comprising:
a non-volatile memory; and
a controller configured to control the non-volatile memory and including a code table generation device, wherein
the code table generation device comprises circuitry configured to:
generate a frequency table including a plurality of symbols and a plurality of appearance frequencies respectively associated with the plurality of symbols based on an appearance frequency of each symbol of the symbols input in a certain period;
add all the appearance frequencies of the symbols input in the certain period and calculate a sum of the appearance frequencies of all the symbols input in the certain period;
rearrange the plurality of symbols in descending order of appearance frequency in the frequency table;
acquire a partial table including symbols ranked M−1 or higher from a frequency table including the plurality of rearranged symbols (M is an integer of 3 or higher), and calculate a sum of the appearance frequencies of the symbols ranked M−1 or higher;
subtract the calculated sum of the appearance frequencies of symbols ranked M−1 or higher from the calculated sum of the appearance frequencies of all the symbols and calculate a sum of the appearance frequencies of symbols ranked M or lower in the frequency table including the plurality of rearranged symbols;
add one symbol corresponding to the sum of the appearance frequencies of the symbols ranked M or lower to the partial table, and rearrange the symbols ranked M−1 or higher and the one symbol in descending order of appearance frequency in a partial table after addition;
generate a first code table corresponding to M symbols including the rearranged symbols ranked M−1 or higher and the one symbol;
equally allocate a code length to the symbols ranked M or lower and generate a second code table corresponding to the symbols ranked M or lower using the allocated code length; and
expand, at an end of a codeword corresponding to the one symbol included in the first code table, a codeword corresponding to the symbol ranked M or lower included in the second code table, and generate a code table corresponding to all the symbols, and
the controller is configured to convert the input symbol into a code using the code table and write data based on the code in the nonvolatile memory.

9. The memory system according to claim 8, wherein the circuitry is configured to generate the first code table used for dynamic Huffman coding.

10. The memory system according to claim 8, wherein
an appearance frequency of a symbol input in the certain period indicates 1 or 0,
the circuitry is configured to, in a case where an appearance frequency of an input predetermined symbol indicates 1, add 1 to the appearance frequency of the predetermined symbol and add 1 to a sum of appearance frequencies of all the symbols.

11. The memory system according to claim 8, wherein the M is set to a value smaller than N/2 in a case where the number of types of the symbols is N (N is an integer of 8 or higher).

12. The memory system according to claim 8, wherein the circuitry is configured to equally allocate the code length to C symbols (C is an integer of 0 or higher) having an appearance frequency of greater than 0 among the symbols ranked M or lower.

13. The memory system according to claim 8, wherein the sum of the appearance frequencies of the symbols ranked M−1 or higher is calculated using M−2 adders arranged in a tree shape.

14. The memory system according to claim 8, wherein
the sum of the appearance frequencies of all the symbols input in the certain period is calculated using n-bit register, and
in a case where the certain period is T cycles and a maximum number of symbols input per cycle is P, the n is set to a value that satisfies P×T≤2ⁿ.

15. A code table generation method comprising:
generating a frequency table including a plurality of symbols and a plurality of appearance frequencies respectively associated with the plurality of symbols based on an appearance frequency of each symbol of symbols input in a certain period;
adding all the appearance frequencies of the symbols input in the certain period, and calculating a sum of the appearance frequencies of all the symbols input in the certain period;
rearranging the plurality of symbols in descending order of appearance frequency in the frequency table;
acquiring a partial table including symbols ranked M−1 or higher from a frequency table including the plurality of rearranged symbols (M is an integer of 3 or higher), and calculating a sum of appearance frequencies of the symbols ranked M−1 or higher;
subtracting the calculated sum of the appearance frequencies of symbols ranked M−1 or higher from the calculated sum of the appearance frequencies of all the symbols and calculating a sum of the appearance frequencies of the symbols ranked M or lower in the frequency table including the plurality of rearranged symbols;
adding one symbol corresponding to the sum of the appearance frequencies of the symbols ranked M or lower to the partial table, and rearranging the symbols ranked M−1 or higher symbol and the one symbol in descending order of appearance frequency in a partial table after the addition;
generating a first code table corresponding to M symbols including the rearranged symbols ranked M−1 or higher and the one symbol;
equally allocating a code length to the symbols ranked M or lower, and generating a second code table corresponding to the symbols ranked M or lower using the allocated code length; and
expanding, at an end of a codeword corresponding to the one symbol included in the first code table, a codeword corresponding to the symbol ranked M or lower included in the second code table, and generating a code table corresponding to all the symbols.

16. The code table generation method according to claim 15, wherein generating the first code table comprises generating the first code table used for dynamic Huffman coding.

17. The code table generation method according to claim 15, wherein
an appearance frequency of a symbol input in the certain period indicates 1 or 0, and
in a case where an appearance frequency of an input predetermined symbol indicates 1, adding 1 to the appearance frequency of the predetermined symbol, and adding 1 to the sum of the appearance frequencies of all the symbols.

18. The code table generation method according to claim 15, wherein the M is set to a value smaller than N/2 in a case where the number of types of the symbols is N (N is an integer of 8 or higher).

19. The code table generation method according to claim 15, wherein equally allocating the code length to the symbols ranked M or lower comprises equally allocating the code length to C symbols (C is an integer of 0 or higher) having an appearance frequency of greater than 0 among the symbols ranked M or lower.

20. The code table generation method according to claim 15, wherein the sum of the appearance frequencies of the symbols ranked M−1 or higher is calculated using M−2 adders arranged in a tree shape.

21. The code table generation method according to claim 15, wherein
the sum of the appearance frequencies of all the symbols input in the certain period is calculated using n-bit register, and
in a case where the certain period is T cycles and a maximum number of symbols input per cycle is P, the n is set to a value that satisfies P×T≤2ⁿ.
